(19) United States
(12) Patent Application Publication
(10) Pub. No.: US 2012/0326300 A1
(43) Pub. Date: Dec. 27, 2012

(54) LOW PROFILE PACKAGE AND METHOD

(75) Inventors: Tao FENG, Santa Clara, CA (US); Will K. WONG, Belmont, CA (US); Ashok S. PRABHU, San Jose, CA (US); Hau T. NGUYEN, San Jose, CA (US); Anindya PODDAR, Sunnyvale, CA (US)

(73) Assignee: NATIONAL SEMICONDUCTOR CORPORATION, Santa Clara, CA (US)

(21) Appl. No.: 13/168,701

(22) Filed: Jun. 24, 2011

(51) Int. Cl. H01L 23/498; H01L 21/50

(52) U.S. Cl. 257/737; 438/107; 438/113; 438/109; 438/108; 257/E21.499; 257/E23.068

(57) ABSTRACT

In a method aspect, a multiplicity of ICs are attached to routing on a structurally supportive carrier (such as a wafer). The dice are encapsulated and then both the dice and the encapsulant layer are thinned with the carrier in place. A second routing layer is formed over the first encapsulant layer and conductive vias are provided to electrically couple the first and second routing layers as desired. External I/O contacts (e.g. solder bumps) are provided to facilitate electrical connection of the second routing layer (or a subsequent routing layer in stacked packages) to external devices. A contact encapsulant layer is then formed over the first encapsulant layer and the second routing layer in a manner that embeds the external I/O contacts at least partially therein. After the contact encapsulant layer has been formed, the carrier itself may be thinned significantly and singulated to provide a number of very low profile packages. The described approach can also be used to form stacked multi-chip packages.

### BACKGROUND OF THE INVENTION

The present invention relates generally to the packaging of integrated circuits.

In the semiconductor field, there are a wide variety of integrated circuit packages that have been used over the years. As technology advances, there are continuing efforts to develop cost effective and reliable packaging techniques that facilitate smaller and/or thinner packages that are useful in a variety of applications. In general, wafer level packaging processes are desirable to provide economies of scale and as die size shrinks, it is desirable to facilitate a fan-out package structures. Thinner packages are often required for miniaturized electronic products and it can also be desirable to provide package designs that facilitate die stacking within a single package. The present application proposed a new packaging approach that can meet these different design objectives.

### SUMMARY OF THE INVENTION

A variety of integrated circuit packages and carrier based wafer level methods of packaging integrated circuits are described. In one method aspect, a multiplicity of integrated circuit dice are attached to a structurally supportive carrier (such as a wafer) having a routing layer thereon. The routing layer on the carrier defines a multiplicity of distinct device areas. After the dice have been attached, an encapsulant layer is formed over the carrier and the routing layer in a manner that encapsulates at least portions of the dice. After the encapsulation, the dice and the encapsulant layer are thinned with the carrier in place. Since the carrier provides structural support, the thickness of the dice and the encapsulation layer may be substantially reduced since the carrier provides structural support and the encapsulant layer is not required to provide substantial structural support during subsequent process steps.

After the thinning of the dice, a second routing layer is formed over the encapsulant layer and conductive vias are provided to electrically couple the first and second routing layers as desired. External I/O contacts (e.g. solder bumps) are also provided to facilitate electrical connection of the second routing layer (or a subsequent routing layer in stacked packages) to external devices. A contact encapsulant layer is then formed over the first encapsulant layer and the second routing layer in a manner that embeds the external I/O contacts at least partially therein. The thickness of the contact encapsulant layer is typically greater than the thickness of the first encapsulant layer such that the contact encapsulant layer provides more structural support than the first encapsulant layer. In some preferred embodiments, the thickness of the contact encapsulant is dictated in significant part by the height of the solder bumps so that the final thickness of the package is not adversely affected by presence of the relatively thick contact encapsulant layer. After the contact encapsulant layer has been formed, the carrier itself may be thinned significantly and singulated to provide a number of very low profile packages. Typically a small portion of the carrier is retained to protect and electrically insulate the first routing layer.

In some preferred embodiments, singulation channels are cut into the contact surface of the wafer structure prior to the thinning of the carrier. Preferably, the singulation channels are arranged to isolate individual device areas and extend fully through both the first and contact encapsulant layers and partially through the carrier. With this approach, the thinning of the carrier serves to singulate the device areas into a multiplicity of separate packaged integrated circuit devices.

The described approach can also be used to form stacked multi-chip packages. In some embodiments, a thin organic passivation layer is formed over the back surface of the dice prior to the formation of the second routing layer such that the second routing layer is formed over the passivation layer. The carrier may take a wide variety of forms. In some embodiments, molded plastic wafers are used as the carrier.

The described approach facilitates cost effective fabrication of very low profile integrated circuit packages. By way of example, in many applications, the carrier and/or the dice may be thinned to a thickness of less than about 50 microns (2 mils), as for example, about 25 microns (1 mil). Often the relative size and height of the solder bumps that form the external I/O contacts are dictated in significant part by design requirements which may call for relatively large contacts. The appropriate thickness of the contact encapsulation layer will be based in large part on the bump height. However, in many embodiments, the thickness of the contact encapsulant layer may be thicker than the combined thickness of the thinned carrier, the first encapsulant layer and the passivation layer. Indeed, in many applications, the thickness of the contact encapsulant layer may constitute at least 50% of the overall height of the resulting packages.

With the described arrangement, the carrier provides structural rigidity necessary for the assembly to be handled by conventional packaging equipment during the packaging process steps. When the packaging is substantially completed with the thinning of the carrier, the contact encapsulant layer cooperates with other layers to provide suitable structural support for the resulting packages.

### BRIEF DESCRIPTION OF THE DRAWINGS

The invention and the advantages thereof, may best be understood by reference to the following description taken in conjunction with the accompanying drawings in which:

FIG. 1 is a flow chart illustrating a wafer method of forming low profile packages in accordance with one embodiment of the present invention.

FIGS. 2(A)-2(K) diagrammatically illustrate steps in the packaging process of FIG. 1.

FIG. 3 diagrammatically illustrates a pair of packaged integrated circuit devices formed in accordance with the process illustrated in FIGS. 1 and 2(a)-2(k).

FIGS. 4(A)-4(E) diagrammatically illustrate some additional steps in a packaging process suitable for forming stacked multi-chip packages in accordance with another embodiment of the invention.

FIG. 5 diagrammatically illustrates a pair of staked multi-chip packages formed in accordance with the process illustrated in FIGS. 4(a)-4(e).

In the drawings, like reference numerals are sometimes used to designate like structural elements. It should also be appreciated that the depictions in the figures are diagrammatic and not to scale.

### DETAILED DESCRIPTION OF THE PREFERRED EMBODIMENTS

The present invention relates generally to the packaging of integrated circuits. More particularly, wafer level methods for packaging integrated circuits are described that are particularly well suited for the formation of very thin packages. In general, package structures for a large number of devices are build in parallel on a carrier that provides structural support during most of the package assembly. Because a carrier is used, various structures within the packages, such as the dice and corresponding encapsulant layer(s), may be thinned significantly, thereby helping reduce the overall thickness of the resulting packages. In the described approaches, an additional encapsulant layer is formed that at least partially embeds the solder bumps that form the external I/O contacts for the package. The appropriate thickness of the contact encapsulant layer will depend in part on the design requirements for the height of the solder bumps that form the external I/O contacts. However, in many applications the desired height of the solder bumps may be relatively large to facilitate good temperature cycling performance, which permits the formation of a relatively thick contact encapsulant layer. This characteristic is used advantageously to provide structural support for the resulting packages. Since the contact encapsulant layer contributes structural support to the resulting packages, the carrier may be thinned substantially which can contribute significantly to the reduction of the overall thickness of the resulting packages.

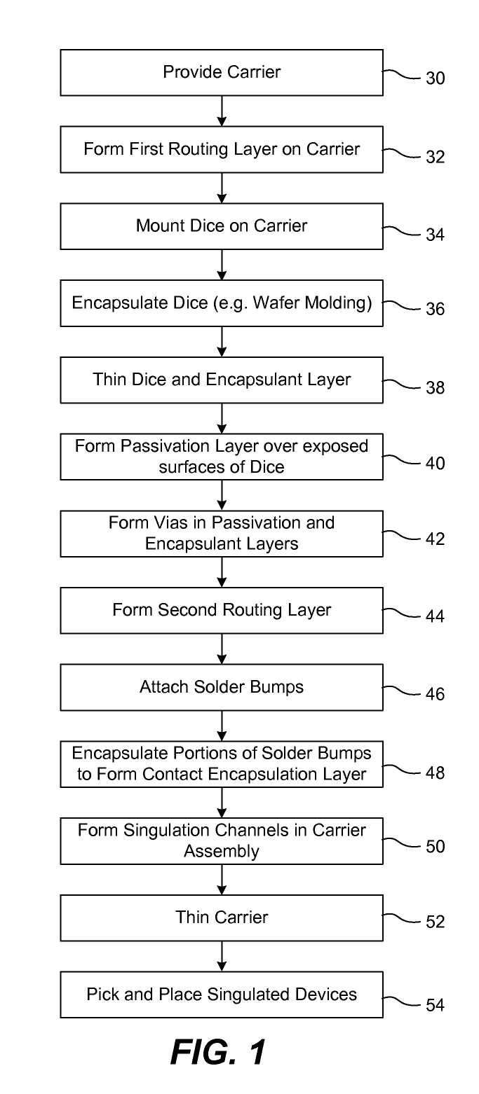

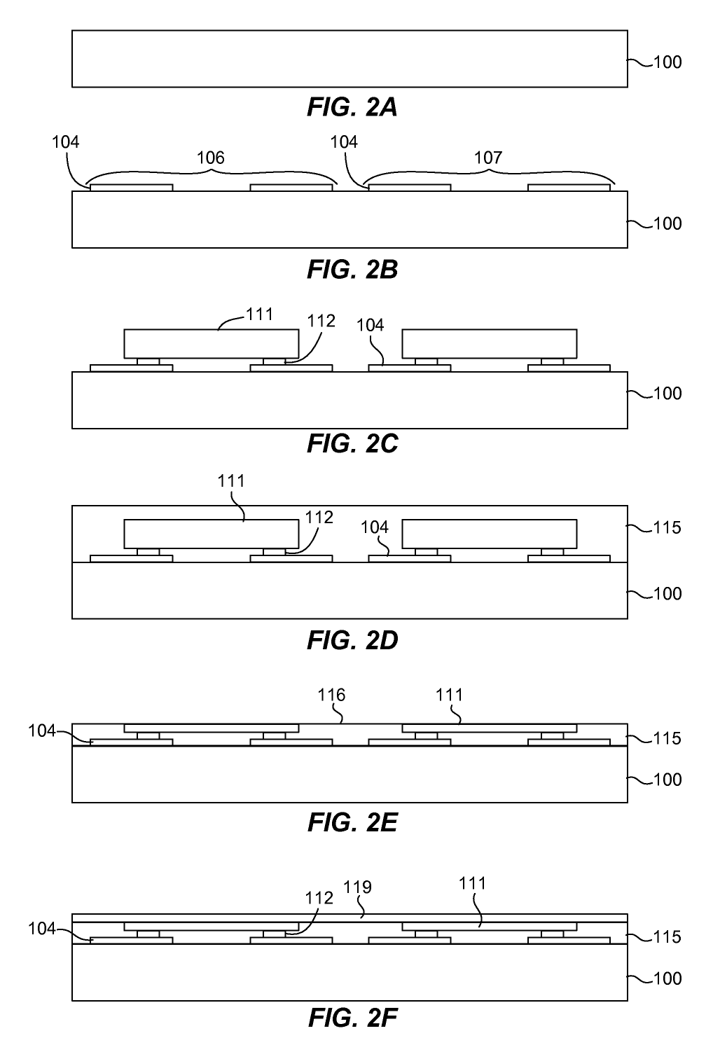

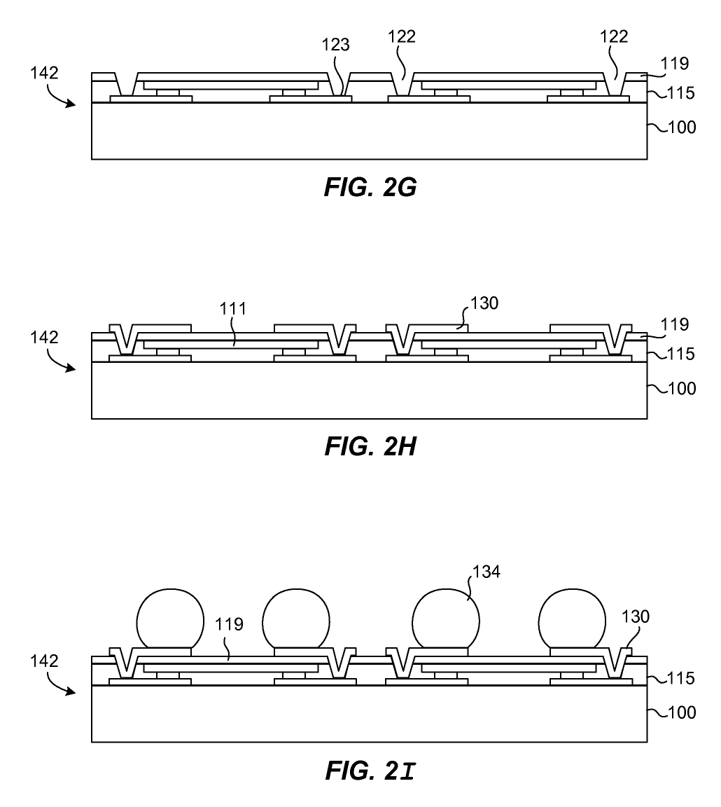

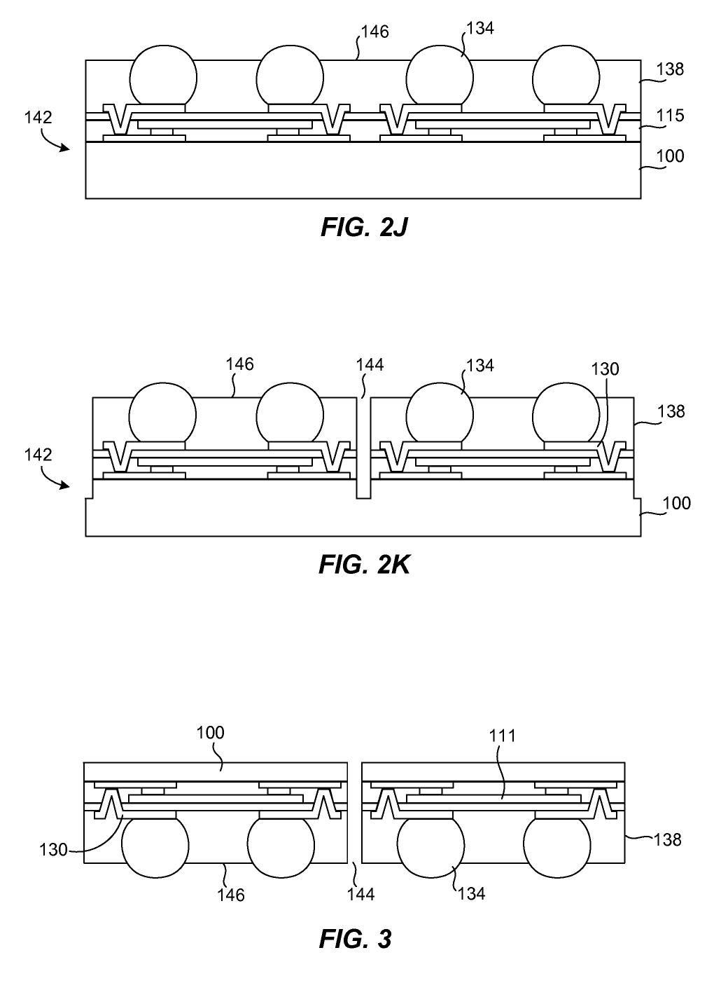

Referring next to FIGS. 1-3, a wafer level method of packaging integrated circuits in accordance with one aspect of the invention will be described. Initially, a carrier 100 is provided. Step 30, FIG. 2(a). The carrier 100 may take any suitable form. By way of example, the carrier may take the form of a silicon wafer, a metal sheet with an insolated surface, a plastic carrier or any other appropriate form. Generally it is desirable for the carrier to have a form factor that is compatible with the packaging equipment that is available to the manufacturer. Since much of the installed base of semiconductor packaging equipment is configured to handle semiconductor wafers (e.g., generally circular type structures) and/or panels (e.g. lead frame or substrate strips or panels) in many applications it may be desirable to create carriers having such geometries. By way of example, cost effective plastic wafer-shaped carriers can readily be formed by using standard wafer encapsulation equipment to form wafer-shaped plastic blanks. Of course, a variety of other carrier geometries can be used as well.

Initially, a patterned conductive routing layer 104 is formed on the wafer as seen in FIG. 2(b). Step 32. The routing layer 104 defines a multiplicity of distinct device areas, each of which is intended to correspond to an individual packaged device after singulation. In the diagrammatic illustrations of FIGS. 2(a)-2(k), only a small segment of a carrier 100 that includes just two device areas 106, 107 is shown. However, it should be appreciated that in actuality the carrier would include many (typically hundreds or thousands) of device areas. The routing layer 104 may be formed and patterned using any of a variety of conventional metallization techniques. By way of example, a metallic seed layer may be deposited using conventional sputtering techniques and the seed layer may thereafter be electroplated using standard techniques such as photomasking the seed layer, lithographically patterning the mask layer, electroplating exposed portions of the seed layer to thicken the routing layer followed by photomask removal and seed layer etch back. Thereafter the routing layer may be thickened using standard electroplating techniques. Of course, a wide variety of other metallization processes may be used as well. Most commonly, the routing layer will be formed from copper or aluminum, although other metals and other conductive materials may be used when desired. The specific layout of traces, contacts and interconnect that make up the routing associated with each device area will vary significantly based on factors such as the specific integrated circuits being packaged and the package's overall pin layout.

After the patterned routing layer 104 has been formed, a multiplicity of dice 111 are attached to the carrier. Step 34, FIG. 2(c). In the illustrated embodiment, each die 111 is flip chip mounted in an associated device area with copper-tin pillars 112 being used to electrically connect to the associated routing layer. Although copper-tin pillars are shown, it should be appreciated that the conductive bumps 112 may take any appropriate form. By way of example, solder bumps, gold wire bonding studs and gold pillars can readily be used in place of the copper-tin pillars. Although not shown from a top view, the routing may include enlarged contact pads that serve as the attachment points for the pillars and traces which electrically connect the contact pads to interconnect pads which facilitate electrical connection to subsequent routing layers and/or external package contacts. In the illustrated embodiment, a single die is attached to each device area 106, 107. However, it should be appreciated that in other embodiments, multi-chip modules may readily be formed in which multiple dice are attached within a single device area.

After the dice have been attached, they are encapsulated. Step 36, FIG. 2(d). By way of example, standard wafer molding works well, although a variety of other conventional encapsulation techniques may be used in alternative embodiments. Any of a variety of conventional encapsulation and/or molding materials may be used as the encapsulant. When the carrier is formed from plastic, the encapsulant 115 may optionally be formed from the same material as the carrier which has the potential advantage of reducing thermal stresses within the package. However, this is not always desirable, since in many cases it may be preferable to form the carrier from a stiffer material than is conventionally used in wafer molding operations. In the illustrated embodiment, the encapsulant 115 is shown to be completely covering the dice. Such an arrangement works well, however it should be appreciated that in other embodiments there is no need for the encapsulant to extend over the top of the dice since the dice will subsequently be thinned.

When dice 111 are mounted on the carrier, they are typically relatively thick (typically several hundreds of microns thick). However, the active portions of dice are typically very thin. Therefore, to decrease the total thickness of the resulting packages, the dice 111 and corresponding portions of the encapsulant layer 115 may be thinned significantly. Step 38. It should be appreciated that this is possible because the carrier 100 provides structural support for the wafer structure during the die attach, encapsulation and subsequent processing steps. Therefore, the layer that includes encapsulation 115 and dice 111 is not required to provide substantial structural support during subsequent process steps.

The dice 111 and the corresponding portions of the encapsulant layer 115 may be thinned using any suitable thinning technique. By way of example, conventional grinding works well. After the thinning, the carrier structure with the thinned dice 111 will generally have a geometry as represented in FIG. 2(e) wherein the back surface of the dice 111 and the exposed surface of the encapsulant 115 are substantially co-planar and form a continuous surface 116.

The actual amount of thinning undertaken in any particular application may vary widely. Preferably, the encapsulant layer 115 and dice 111 are thinned to provide an encapsulant layer thickness of less than 100 microns, and thicknesses of no more than about 85 microns, or 60 microns are even more preferred. By way of example, chip thicknesses on the order of 25-50 microns (1-2 mils) work well in many applications, although even thinner chips can readily be obtained.

It should be appreciated that the encapsulant layer 115 will be thicker than the dice due to the presence of the interconnects (bumps/pillars) 112 and the routing layer 104. By way of example, in some embodiments the interconnects may also be on the order of 1 mil (25 microns) although again, both thinner and thicker interconnect structures may be used. The routing layer 104 will also have a thickness which will vary with the needs of any particular package. For example, routing layer thicknesses on the order of 10 microns are not uncommon, although again, the actual thickness may be widely varied. For illustrative purposes, if a die is thinned to a thickness of about 2 mils (50 microns), the interconnects have a height of about 1 mil (25 microns) and the routing layer has a thickness of about 10 microns, the encapsulant layer 115 may have an overall thickness of less than about 100 microns (e.g., about 85 microns if the tolerances were tight).

After the dice have been thinned, a second routing layer is formed over the dice and encapsulant layer. Step 44. In many applications, some portions of the routing will extend over the dice. Since the exposed surface of the die is somewhat electrically conductive, a thin passivation layer 119 is preferably applied over the exposed surface of the dice to electrically insulate the dice 111 from the subsequently applied second routing layer. Step 40. Any of a variety of conventional passivation materials may be used to form passivation layer 119. By way of example conventional organic polymer based passivation materials that are commonly used in semiconductor packaging applications such as polyimide (PI), Polybenzobisoxazole (PBO), and benzocyclobutene (BCB) based formulations work well as the passivation material. In the illustrated embodiment, the passivation layer 119 extends over the entire exposed surface 116 since it is typically most cost effective to simply apply the passivation material over the entire surface of the carrier structure. However, in theory, the passivation 119 could be limited to the exposed regions of the dice or regions where the second routing layer overlies the dice if desired. In embodiments in which the routing layer does not overlie the dice, the passivation layer 119 is optional.

After the wafer has been thinned and any desired passivation has been applied, a second routing layer 130 is formed over the first encapsulant layer 115 and conductive vias are provided to electrically couple the first and second routing layers as desired. In the illustrated method, vias 122 are formed in the passivation surface of the wafer. The vias extend through the passivation layer 119 and the encapsulant layer 115. Step 42, FIG. 2(g). The vias 122 are positioned at appropriate locations to expose interconnect regions 123 of the first routing layer 104. The vias 122 may be formed using any appropriate technique. By way of example, laser drilling works well although other suitable etching techniques may be used in alternative embodiments. The vias are subsequently filled with a conductive material to electrically connect the first and second routing layers at any desired interconnect locations.

After the vias 122 are formed, the second patterned routing layer 130 is formed over the passivation layer 119 and the encapsulant layer 115. Step 44, FIG. 2(h). Again, conventional semiconductor metallization techniques can be used to form and pattern the routing layer 130. When conformal metal deposition techniques are used, the vias 122 will be at least partially filled with the deposited metal. Since the vias 122 expose interconnect regions 123 on the first routing layer, the metallization deposited therein during the deposition of the second routing layer inherently electrically connects the first and second routing layers.

After the second routing layer 130 has been formed, solder bumps 134 are attached to associated contact pads located in the second routing layer. Step 46, FIG. 2(i). The solder bumps 134 form the external I/O contacts for the finished packages 150. The solder bumps may be formed or attached using a variety of conventional solder bump formation/attachment techniques. Although solder bumps are used in the illustrated embodiment, is should be appreciated that other suitable contact structures could be used in place of the solder bumps to form the external I/O contacts when desired.

After the solder bumps have been attached, a second encapsulant layer (referred to herein as a contact encapsulant layer 138) is applied over the second routing layer in a manner that embeds the solder bumps (i.e., the external I/O contacts) therein. Step 48, FIG. 2(j). The thickness of the contact encapsulant layer 138 is typically substantially greater than the thickness of the first encapsulant layer 115 such that the contact encapsulant layer provides more structural support to the finished packages 150 than the first encapsulant layer as will be described in more detail below. By way of example, contact encapsulant layers having a thickness of at least approximately 150 microns work well for many applications, although the actual thickness of the contact encapsulant layer may vary widely. It should be noted that in some applications where lower profile contacts are used, it may be desirable to limit the thickness of the contact encapsulant layer to less than 150 microns. For example, contact encapsulant layer thicknesses on the order of 100-120 microns work well in some applications.

Like the first encapsulation layer, the contact encapsulation layer 138 may be formed using any suitable encapsulation technique. By way of example, standard wafer molding works well. If the encapsulant is applied in a manner that completely covers the solder bumps, then a subsequent step of exposing the solder bumps would be required. However, at will be appreciated by those familiar with molding operations in semiconductor packaging applications, the molding can readily be performed in a manner that leaves portions of the solder bumps exposed. For example, this may be accomplished by placing a compliant tape in the mold and positioning the carrier assembly in the mold in a manner that presses portions of the solder bumps into the tape to thereby prevent molding material from covering tip portions of the solder bumps during the molding operation. Like the first encapsulant layer, a variety of conventional encapsulants and/or molding materials may be used to form the contact encapsulant layer. Typically, the contact encapsulant layer would be formed from the same material as the first encapsulant layer, although this is not required. To the extent that there are any indentations in the metallization (e.g. over the now conductive vias), the molding material will fill the indentations as well.

After the contact encapsulant layer has been formed, the carrier 100 itself may be thinned significantly and the carrier assembly 142 is singulated to provide a number of very low profile packages. In the illustrated embodiment, singulation channels 144 are cut into the contact surface 146 of the carrier assembly (wafer structure) prior to the thinning of the carrier. Step 50, FIG. 2(k). Preferably, the singulation channels are arranged to isolate individual device areas and extend fully through both the first and contact encapsulant layers 115, 138 and partially (but not fully) through the carrier 100. The singulation channels 144 may be formed by standard wafer sawing, laser cutting or any other suitable technique.

After the singulation channels 144 have been formed, the carrier 100 is thinned to further reduce the overall height of the resultant packages. Step 52. Again, grinding works well to thin the carrier, although in alternative embodiments, other thinning techniques may be used in place of grinding. Preferably, the grinding sacrifices most, but not the entire carrier 100, so that some portion of the carrier remains to form the back surface of the final packages. Thus, the remaining portion of the carrier 100 mechanically protects and electrically insulates the first routing layer 104 in the final packages 150. The singulation channels 144 are preferably cut to a depth that extends past the level in the carrier that is intended to form the back surface of the package. Thus, the grinding extends into the singulation channel such that the discrete devices are actually separated by the grinding operation thereby resulting in a multiplicity of discrete packages 150 as illustrated in FIG. 3.

As will be appreciated by those familiar with wafer grinding operations, grinding is typically performed with wafer structure secured to a tape. Thus, the contact surface of the carrier structure 142 is secured to a grinding tape prior to the grinding operation. With this approach, the thinning of the carrier serves to singulate the device areas into a multiplicity of separate packaged integrated circuit devices which remain held in place by the grinding tape (not shown). The resultant packages 150 may then be picked and placed directly from the grinding tape if the pick and place equipment is arranged to handle face down packages. Step 54. Alternatively, if the pick and place equipment requires face up packages, the singulated packages can readily be transferred en mass to a back mount tape.

It should be appreciated that the described approach facilitates cost effective formation of very low profile integrated circuit packages. By way of example, the carrier and/or the dice may readily be thinned to thicknesses of less than four mils (100 microns) and more preferably less than 2 mils (50 microns) and even more preferably less than 30 microns each. By way of example thinning to carrier and dice thicknesses on the order of about 1 mil (25 microns) works well in many applications and even thinner dimensions are readily obtainable.

The thickness of the contact encapsulant is dictated in significant part by the height of the solder bumps so that the final thickness of the package is not adversely affected by presence of the relatively thick contact encapsulant layer. Often the relative size and height of the solder bumps 134 that form the external I/O contacts are dictated in significant part by package design requirements which may call for relatively large contacts. Since the height of the solder bumps may be dictated in part by other factors, the corresponding thickness of the contact encapsulant layer often will not add to overall package height. Since the height of the solder bumps is often relatively high compared to the thickness of the other layers (as for example greater than 150 microns), the contact encapsulant layer can provide significant structural support for the resulting packages 150. Thus, with the described approach, the carrier provides structural rigidity suitable for handling by conventional packaging equipment during the packaging process steps. When the packaging is substantially completed with the thinning of the carrier, the contact encapsulant layer cooperates with other layers to provide suitable structural support for the resulting packages.

The actual and relative thicknesses of the various layers may vary widely based on the needs of any particular application. However, in many embodiments, the thickness of the contact encapsulant layer will be thicker than the combined thickness of the thinned carrier, the first encapsulant layer and the passivation layer. Indeed, in many applications, the thickness of the contact encapsulant layer may constitute 50% or more of the overall height of the resulting packages. However, this is not a requirement and some of the benefits of the present invention may be obtained even when the contact encapsulation layer constitutes less than 50% of the overall height of the resulting packages. In one such specific implementation, the contact encapsulation layer is at least 100 microns thick and constitutes at least 40% of the overall height of the resulting packages.

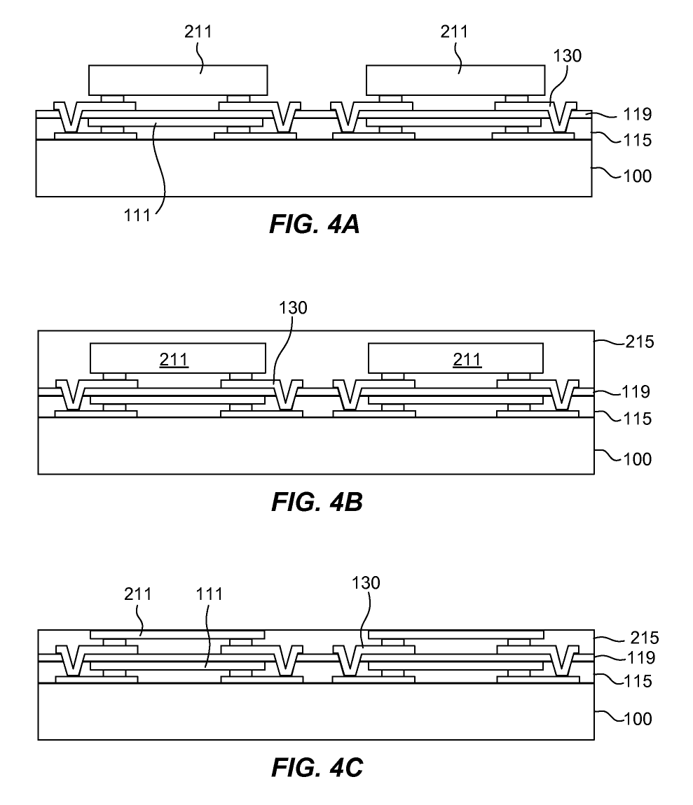

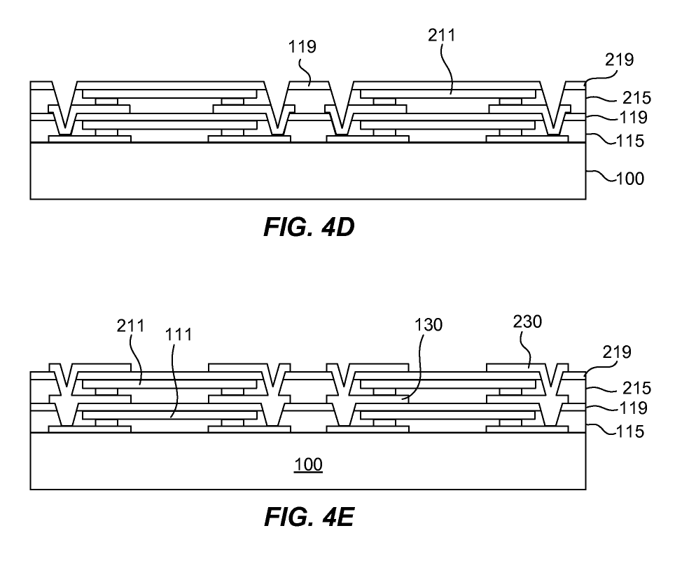

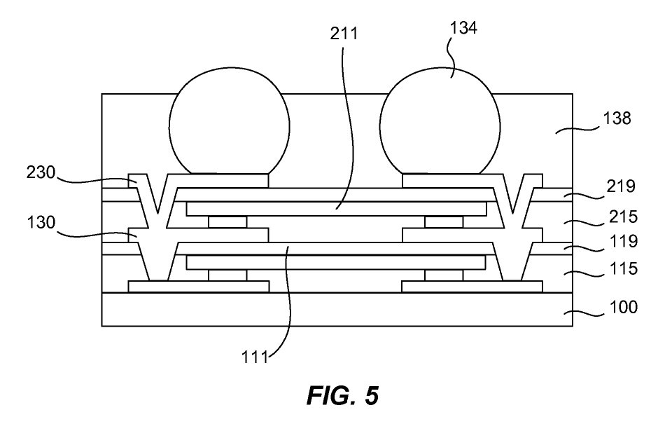

The described packaging approach can also be used to form stacked multi-chip packages. Referring next to FIGS. 4(a)-4(e) and FIG. 5, a variation that facilitates the packaging of stacked multi-chip devices will be described. Generally, the stacked packages are formed in much the same manner as the single chip packages shown in FIGS. 1 and 2 are repeated. However, after the fabrication of the second routing layer 130 (Step 44—FIG. 2(h)), steps 34-44 are essentially repeated to stack a second die over the first die in each package. More specifically, a second set of dice 211 are mounted to the second routing layer as shown in FIG. 4(a). As with the first set of dice, the second set of dice 211 are encapsulated as illustrated in FIG. 4(b). Typically the same type of encapsulation process (e.g. molding) and the same type of encapsulant would be used to form the second encapsulant layer 215. The second encapsulant layer 215 and the second set of dice are then thinned (FIG. 4(c)). Thereafter, as best seen in FIG. 4(d), a passivation layer 219 is formed over the thinned surface of the carrier and vias 222 are formed to expose interconnect regions of the second routing layer 130. A third patterned routing layer 230 is then formed over the passivation layer as seen in FIG. 4(e). At this point, each device area has a pair of stacked dice. If just two stacked dice are required, the external contacts are secured to the third routing layer 230 and the remainder of the packaging process may continue as described above with respect to FIGS. 1 and 2. If higher stacks are desired, then steps 34-44 may be repeated as many times as necessary to create the desired chip stacks.

Like the first encapsulant layer, the second encapsulant layer (and any subsequent encapsulation layers) may be thinned to thicknesses of less than approximately 100 microns, and thickness of not more than 85 microns or 60 are preferable in many application.

In the embodiment illustrated in FIG. 5, the second die is stacked directly above the first die. Although such an arrangement has many applications, it should be appreciated that the various layers are typically planarized and that from a process standpoint, there is no need for the chips to stack directly on top of one another. Thus, if desired, the chips mounted on different layers could be horizontally displaced as much as desired, and as mentioned above, any particular layer could support more than one integrated circuit or other electrical components thereon. For example, passive components such as capacitors, inductors and resistors could readily be placed within the packages and electrically connected as appropriate by the various routing layers.

It should also be apparent that in packages having more than two component layers, that vias can readily be formed that electrically connect routing layers that are not adjacent one another. For example, selected portions of a first routing layer could readily be electrically coupled to associated portions of a third routing layer, without requiring electrical connection to any components carried on the second routing layer.

Although only a few embodiments of the invention have been described in detail, it should be appreciated that the invention may be implemented in many other forms without departing from the spirit or scope of the invention. Although specific processes have been suggested for some of the described packaging steps (e.g., encapsulation, metallization, passivation, die attach, etc.), it should be appreciated that the invention is not limited to the described embodiments since a wide variety of conventional processed can be used to perform each of the described steps and it is anticipated that future technical advancements may provide still more appropriate techniques for performing such steps.

In the discussions above, reference is sometimes made to wafer level processing. It should be appreciated that the term wafer level processing is not intended to be limited to processing done on carriers having the geometry of traditional semiconductor wafers. Rather, it simply indicates that the carrier panels have a relatively large number of device areas thereon (e.g. tens, or hundreds or thousands of device areas) that may in many respects be processed in parallel to provide economies of scale. Most often, such carriers are arranged to include one or more two dimensional arrays of device areas.

Although the described molded plastic carriers having wafer style form factors work well, it should be appreciated that the carriers may be fabricated from a wide variety of alternative materials and the form factor of the carrier may be varied widely to meet the needs of any particular application. Therefore, the present embodiments should be considered illustrative and not restrictive and the invention is not to be limited to the details given herein, but may be modified within the scope and equivalents of the appended claims.

What is claimed is:

1. A method of packaging integrated circuits comprising:
forming a first patterned, conductive, routing layer on a carrier, wherein the routing layer defines a multiplicity of device areas;
mounting a multiplicity of integrated circuit dice on the carrier, wherein each integrated circuit die is mounted in the region of an associated device area and is electrically connected to contacts formed in the first routing layer within the associate device area;
forming a first encapsulant layer over the carrier that covers the first routing layer and encapsulates at least portions of the integrated circuit dice;
thinning the integrated circuit dice and the first encapsulant layer with the carrier in place;
forming vias in the first encapsulant layer to expose selected interconnect regions of the first routing layer;
forming a second patterned routing layer over the first encapsulant layer, wherein the second routing layer is electrically connected to the first routing layer;
creating external I/O contacts arranged to facilitate electrical connection to an external device;
forming a contact encapsulant layer over the first encapsulant layer and the second routing layer, wherein the external I/O contacts are at least partially embedded in the contact encapsulant layer; and
thinning the carrier after the formation of the contact encapsulant layer.

2. A method as recited in claim 1 further comprising:
cutting singulation channels that extend fully through the first and contact encapsulant layers and partially through the carrier, wherein the singulation channels are arranged to isolate individual device areas; and
wherein the thinning of the carrier occurs after the formation of the singulation channels and the thinning extends at least to the singulation channels to thereby provide a multiplicity of singulated integrated circuit packages.

3. A method as recited in claim 1 wherein the external I/O contacts are solder bumps that are attached to I/O contact pads formed in the second routing layer.

4. A method as recited in claim 1 further comprising:
mounting and electrically connecting a second set of integrated circuit dice to associated contacts formed in the second routing layer;
forming a second encapsulant layer over the first encapsulant layer and the second routing layer, wherein the second encapsulant layer at least partially encapsulates the second set of integrated circuit dice;
thinning the second set of integrated circuit dice and the second encapsulant layer with the carrier in place;
forming vias in the second encapsulant layer to expose selected interconnect regions of the second routing layer; and
forming a third routing layer over the second encapsulant layer, wherein the third routing layer is electrically connected to the second routing layer and wherein the contact encapsulant layer is formed over the second encapsulant layer and the third routing layer; and
whereby a multiplicity of stacked multi-chip packages are formed.

5. A method as recited in claim 1 further comprising applying a thin organic passivation layer over the first encapsulation layer after the thinning of the integrated circuit dice to passivate an exposed back surface of the dice prior to the formation of the second routing layer such that the second routing layer is formed over the passivation layer.

6. A method as recited in claim 1 wherein:
the carrier is a plastic wafer formed by molding; and
the second and contact encapsulant layers are formed by wafer molding.

7. A method as recited in claim 1 wherein the second routing layer is formed at least in part by deposition and the vias are at least partially filled by portions of the second routing layer to electrically couple the second routing layer to the first routing layer.

8. A method as recited in clam 1 wherein the vias are formed by laser drilling and the first routing layer serves as an etch stop for the laser drilling.

9. A method as recited in claim 2 further comprising applying a thin organic passivation layer over the first encapsulation layer after the thinning of the integrated circuit dice to passivate an exposed back surface of the dice prior to the formation of the second routing layer such that the second routing layer is formed over the passivation layer, and wherein:
the first and contact encapsulant layers are formed by wafer molding;
after the thinning of the carrier, the thickness of the contact encapsulant layer is no less than the combined thickness of the thinned carrier, the first encapsulant layer and the passivation layer;
the integrated circuit dice are flip chip mounted onto the carrier; and
conductive bumps used to electrically connect the integrated circuit dice to the first routing layer are selected from the group consisting of solder bumps, copper-tin bumps, gold wire bonding studs, gold pillars and copper pillars.

10. An integrated circuit package comprising:
a thinned carrier layer having a first patterned conductive routing layer thereon;
an integrated circuit die flip chip mounted on the carrier, the die being electrically connected to the first routing layer;
a first encapsulant layer that covers the first routing layer and partially encapsulates the die, wherein a first surface of the encapsulant layer is substantially co-planar with a back surface of the die;
a second patterned routing layer formed over the first encapsulant layer
a set of conductive vias that extend through the first encapsulant layer to electrically interconnect the first and second routing layers;
a plurality of solder I/O bumps arranged to facilitate electrical connection to an external device; and
a contact encapsulant layer positioned over the first encapsulant layer and the second routing layer, wherein the I/O bumps are at least partially embedded in the contact encapsulant layer and the thickness of the contact encapsulant layer is no less than the combined thickness of the thinned carrier layer and the first encapsulant layer.

11. An integrated circuit package as recited in claim 10 wherein the thickness of the contact encapsulant layer constitutes at least 50% of the overall height of the integrated circuit package.

12. An integrated circuit package as recited in claim 10 wherein the thickness of the contact encapsulant layer is at least 100 microns and constitutes at least 40% of the overall height of the integrated circuit package.

13. An integrated circuit package as recited in claim 10 further comprising an organic passivation layer that covers the first surface of the first encapsulant layer and the back surface of the die, wherein the second patterned routing layer is formed over the passivation layer

14. An integrated circuit package as recited in claim 13 further comprising:
a second integrated circuit die attached and electrically connected to the second routing layer;
a second encapsulant layer that covers the passivation layer and the second routing layer and partially encapsulates the second die, wherein a first surface of the second encapsulant layer is substantially co-planar with a back surface of the second die;
a third patterned routing layer formed over the second encapsulant layer, wherein the contact encapsulant layer is formed over the second encapsulant layer and the third routing layer; and
a second set of conductive vias that extend through the second encapsulant layer to electrically interconnect the second and third routing layers.

15. An integrated circuit package as recited in claim 10 wherein the carrier is formed from plastic.

16. An integrated circuit package as recited in claim 10 wherein:
the thickness of the first encapsulant layer is less than approximately 100 microns;
the thickness of the carrier is less than approximately 50 microns; and
the thickness of the contact encapsulant layer is greater than approximately 150 microns.

17. An integrated circuit package as recited in claim 13 wherein:
the thickness of the first encapsulant layer no greater than approximately 85 microns;
the carrier is formed from plastic and has a thickness of less than approximately 30 microns; and
the thickness of the contact encapsulant layer is greater than approximately 100 microns;
the passivation layer is formed from a polymer material selected from the group consisting of polyimide, PBO and BCB; and
the thickness of the contact encapsulant layer constitutes at least 40% of the overall height of the integrated circuit package.
